(19) United States
(12) Patent Application Publication
(10) Pub. No.: US 2026/0098196 A1
(43) Pub. Date: Apr. 9, 2026

(54) CHEMICAL-MECHANICAL POLISHING COMPOSITION FOR SILVER POLISHING

(71) Applicant: ENTEGRIS, INC., Billerica, MA (US)

(72) Inventors: ChenHao Wang, Taichung City (TW); Cheng-Yuan Ko, Kaohsiung City (TW)

(21) Appl. No.: 19/353,335

(22) Filed: Oct. 8, 2025

Related U.S. Application Data
(60) Provisional application No. 63/705,379, filed on Oct. 9, 2024.

(51) Int. Cl. C09K 3/14; B24B 57/02

(52) U.S. Cl. CPC C09K 3/1463; B24B 57/02

(57) ABSTRACT

The invention provides a chemical-mechanical polishing composition comprising: (a) an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (e) water. The invention also provides a method of chemically-mechanically polishing a substrate, especially a substrate comprising silver, using said composition.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

One metal of interest in semiconductor applications is silver, which shares many properties and characteristics in common with copper vis-à-vis CMP, such as corrosion properties and passivating properties. For example, both silver and copper effectively form films with and are passivated by benzotriazole. In addition, Cu and Ag both readily dissolve in acidic pH with a formation of metal ions (for Cu, Cu⁺¹ and Cu⁺² and for silver Ag⁺¹) and passivate at higher pHs with a formation of oxides. Despite the interest in silver, and the similarities to copper, accurate tuning between silver corrosion mode (i.e., high silver removal rate but high corrosion) and silver passivation mode (i.e., low corrosion but low silver removal rate) remains a challenge.

Accordingly, there is an ongoing need to develop new polishing compositions and methods that provide relatively high rates of removal of silver, as well as reduce dishing and erosion. The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (e) water.

The invention further provides a method of chemically-mechanically polishing a substrate comprising: (i) providing a substrate, (ii) providing a polishing pad, (iii) providing a chemical-mechanical polishing composition comprising: (a) a an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (e) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### BRIEF DESCRIPTION OF THE DRAWINGS

FIG. 1 is a graph showing the silver removal rate (Å/min) as a function of polishing promoter compound, as described in Example 1.

FIG. 2 is a graph showing the silver removal rate (Å/min) as a function of topography control agent, as described in Example 2.

FIG. 3 is a graph showing the silver removal rate (Å/min) provided by comparative polishing compositions, as described in Example 3.

### DETAILED DESCRIPTION OF THE INVENTION

The invention provides a chemical-mechanical polishing composition comprising: (a) an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (e) water.

The polishing composition comprises an abrasive selected from a silica abrasive, an alumina abrasive (e.g., α-alumina), and a combination thereof. As used herein, the terms “abrasive,” “particle,” and “abrasive particle” can be used interchangeably, and can refer to any silica abrasive, alumina abrasive, or a combination thereof.

The abrasive (e.g., alumina, silica, or a combination thereof) preferably is colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]<0.5). More preferably, the value of {[B]−[T]}/[C] is less than or equal to 0.3, and most preferably is less than or equal to 0.1.

In some embodiments, the polishing composition comprises a silica abrasive. As used herein, the terms “silica abrasive,” “silica abrasive particle,” and “silica particle” can be used interchangeably, and can refer to any silica particle (e.g., colloidal silica particle). The silica can be of any suitable form such as wet-process type silica, fumed silica, or combinations thereof. For example, the silica can comprise wet-process type silica particles (e.g., condensation-polymerized or precipitated silica particles).

The silica abrasive (e.g., colloidal silica particles) can be prepared by various methods, some examples of which are commercially used and known. Useful silica abrasive particles include precipitated or condensation-polymerized silica, which may be prepared using known methods, such as by methods referred to as the “sol gel” method or by silicate ion-exchange. Condensation-polymerized silica particles are often prepared by condensing Si(OH)₄ to form substantially spherical (e.g., spherical, ovular, or oblong) particles. The precursor Si(OH)₄ may be obtained, for example, by hydrolysis of high purity alkoxysilanes, or by acidification of aqueous silicate solutions. U.S. Pat. No. 5,230,833 describes a method for preparing colloidal silica particles in solution.

In some embodiments, the silica abrasive is a colloidal silica particle. As known to one of ordinary skill in the art, colloidal silicas are suspensions of fine amorphous, nonporous and typically spherical particles in a liquid phase. The colloidal silica can take the form of condensation-polymerized or precipitated silica particles. In some embodiments, the silica is in the form of wet-process type silica particles. The particles, e.g., colloidal silica, can have any suitable average size (i.e., average particle diameter). If the average abrasive particle size is too small, the polishing composition may not exhibit sufficient removal rate. In contrast, if the average abrasive particle size is too large, the polishing composition may exhibit undesirable polishing performance such as, for example, poor substrate defectivity. Such colloidal silica particles may be aggregated or non-aggregated. Non-aggregated particles are individually discrete particles that may be spherical or nearly spherical in shape, but can have other shapes as well (such as generally elliptical, square, or rectangular cross-sections). Aggregated particles are particles in which multiple discrete particles are clustered or bonded together to form aggregates having generally irregular shapes.

In some embodiments, the silica abrasive is a pyrogenic silica particle. Pyrogenic silica (also referred to as fumed silica) is produced via a flame hydrolysis process in which a suitable feedstock vapor (such as silicon tetrachloride) is combusted in a flame of hydrogen and oxygen. Molten particles of roughly spherical shapes are formed in the combustion process, the diameters of which may be varied via process parameters. These molten spheres, commonly referred to as primary particles, fuse with one another by undergoing collisions at their contact points to form branched, three dimensional chain-like aggregates. Fumed silica abrasives are commercially available from a number of suppliers including, for example, Cabot Corporation, Evonik, and Wacker Chemic.

The silica abrasive (e.g., colloidal silica particle) can be modified (e.g., surface modified) or unmodified, and have a negative native zeta potential, a positive native zeta potential, or a neutral native zeta potential. As used herein, the phrase “native zeta potential” refers to the zeta potential of the silica abrasive prior to adding the silica abrasive to the polishing composition. For example, the native zeta potential can refer to the zeta potential of a silica abrasive prior to adding the silica abrasive to the polishing composition as measured in a neutral (i.e., pH of about 7) aqueous solution.

A skilled artisan will be able to determine whether the silica abrasive, prior to adding the silica abrasive to the polishing composition, has a negative native zeta potential, a positive native zeta potential, or a neutral native zeta potential. The charge on dispersed particles such as a silica abrasive (e.g., colloidal silica particles) is commonly referred to as the zeta potential (or the electrokinetic potential). The zeta potential of a particle refers to the electrical potential difference between the electrical charge of the ions surrounding the particle and the electrical charge of the bulk solution of the composition in which it is measured (e.g., the liquid carrier and any other components dissolved therein). The zeta potential is typically dependent on the pH of the aqueous medium. For a given polishing composition, the isoelectric point of the particles is defined as the pH at which the zeta potential is zero. As the pH is increased or decreased away from the isoelectric point, the surface charge (and hence the zeta potential) is correspondingly decreased or increased (to negative or positive zeta potential values). The native zeta potential and the zeta potential of the polishing composition may be obtained using the Model DT-1202 Acoustic and Electro-acoustic spectrometer available from Dispersion Technologies, Inc. (Bedford Hills, N.Y.). As used herein, the phrase “negative zeta potential” refers to a silica abrasive that exhibits a negative surface charge when measured in the polishing composition. As used herein, the phase “positive zeta potential” refers to a silica abrasive that exhibits a positive surface charge when measured in the polishing composition. As used herein, the phase “neutral zeta potential” refers to a silica abrasive that exhibits no (i.e., −0.5 mV to 0.5 mV) surface charge when measured in the polishing composition.

The silica abrasive (i.e., silica abrasive particles) can have any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, La.) or the Zetasizer® available from Malvern Instruments®. Such instruments generally report an average particle size for a silica dispersion.

Accordingly, the silica abrasive (e.g., silica particles or colloidal silica particles) can have an average particle diameter of about 10 nm or more, e.g., about 15 nm or more, about 20 nm or more, about 25 nm or more, about 30 nm or more, about 35 nm or more, about 40 nm or more, about 45 nm or more, about 50 nm or more, about 60 nm or more, about 70 nm or more, or about 80 nm or more. Alternatively, or in addition, the silica abrasive can have an average particle diameter of about 200 nm or less, e.g., about 175 nm or less, about 150 nm or less, about 140 nm or less, about 130 nm or less, about 125 nm or less, about 120 nm or less, about 110 nm or less, about 100 nm or less, about 75 nm or less, about 50 nm or less, or about 40 nm or less. Thus, the silica abrasive can have an average particle diameter bounded by any two of the aforementioned endpoints.

For example, in some embodiments, the silica abrasive (e.g., silica particles or colloidal silica particles) can have an average particle diameter of about 10 nm to about 200 nm, e.g., about 10 nm to about 175 nm, about 10 nm to about 150 nm, about 10 nm to about 140 nm, about 10 nm to about 130 nm, about 10 nm to about 125 nm, about 10 nm to about 120 nm, about 10 nm to about 110 nm, about 10 nm to about 100 nm, about 10 nm to about 75 nm, about 10 nm to about 50 nm, about 10 nm to about 40 nm, about 20 nm to about 200 nm, about 20 nm to about 175 nm, about 20 nm to about 150 nm, about 20 nm to about 140 nm, about 20 nm to about 130 nm, about 20 nm to about 125 nm, about 20 nm to about 120 nm, about 20 nm to about 110 nm, about 20 nm to about 100 nm, about 20 nm to about 75 nm, about 20 nm to about 50 nm, about 20 nm to about 40 nm, about 30 nm to about 200 nm, about 30 nm to about 175 nm, about 30 nm to about 150 nm, about 30 nm to about 140 nm, about 30 nm to about 130 nm, about 30 nm to about 125 nm, about 30 nm to about 120 nm, about 30 nm to about 110 nm, about 30 nm to about 100 nm, about 30 nm to about 75 nm, about 30 nm to about 50 nm, about 30 nm to about 40 nm, about 40 nm to about 200 nm, about 40 nm to about 175 nm, about 40 nm to about 150 nm, about 40 nm to about 140 nm, about 40 nm to about 130 nm, about 40 nm to about 125 nm, about 40 nm to about 120 nm, about 40 nm to about 110 nm, about 40 nm to about 100 nm, about 40 nm to about 75 nm, about 40 nm to about 50 nm, about 50 nm to about 200 nm, about 50 nm to about 175 nm, about 50 nm to about 150 nm, about 50 nm to about 140 nm, about 50 nm to about 130 nm, about 50 nm to about 125 nm, about 50 nm to about 120 nm, about 50 nm to about 110 nm, about 50 nm to about 100 nm, about 50 nm to about 75 nm, about 60 nm to about 200 nm, about 60 nm to about 175 nm, about 60 nm to about 150 nm, about 60 nm to about 140 nm, about 60 nm to about 130 nm, about 60 nm to about 125 nm, about 60 nm to about 120 nm, about 60 nm to about 110 nm, about 60 nm to about 100 nm, about 60 nm to about 75 nm, about 70 nm to about 200 nm, about 70 nm to about 175 nm, about 70 nm to about 150 nm, about 70 nm to about 140 nm, about 70 nm to about 130 nm, about 70 nm to about 125 nm, about 70 nm to about 120 nm, about 70 nm to about 110 nm, about 70 nm to about 100 nm, about 80 nm to about 200 nm, about 80 nm to about 175 nm, about 80 nm to about 150 nm, about 80 nm to about 140 nm, about 80 nm to about 130 nm, about 80 nm to about 125 nm, about 80 nm to about 120 nm, about 80 nm to about 110 nm, or about 80 nm to about 100 nm.

In some embodiments, the polishing composition comprises an alumina abrasive. As used herein, the terms “alumina abrasive,” “alumina abrasive particle,” and “alumina particle” can be used interchangeably, and can refer to any alumina particle (e.g., colloidal alumina particle). In some embodiments, the alumina abrasive is α-alumina. The α-alumina can be any suitable form of α-alumina.

The alumina abrasive (i.e., alumina abrasive particles) can have any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, La.) or the Zetasizer® available from Malvern Instruments®. Such instruments generally report an average particle size for an alumina dispersion.

Accordingly, the alumina abrasive (e.g., α-alumina abrasive particles) can have an average particle size of about 90 nm or more, e.g., about 100 nm or more, about 110 nm or more, about 120 nm or more, about 130 nm of more, about 140 nm or more, or about 150 nm or more. Alternatively, or in addition, the alumina particles can have an average particle size of about 300 nm or less, e.g., about 290 nm or less, about 280 nm or less, about 270 nm or less, about 260 nm or less, about 250 nm or less, about 240 nm or less, about 230 nm or less, about 220 nm or less, about 210 nm or less, or about 200 nm or less. Thus, the alumina particles can have an average particle size bounded by any two of the aforementioned endpoints. For example, the alumina particles can have an average particle size of about 90 nm to about 300 nm, e.g., about 100 nm to about 280 nm, about 100 nm to about 260 nm, about 100 nm to about 240 nm, about 120 nm to about 240 nm, about 120 nm to about 220 nm, or about 120 nm to about 200 nm.

In certain embodiments, the polishing composition comprises a silica abrasive and an alumina abrasive.

The abrasive can be present in the polishing composition in any suitable amount. If the polishing composition of the invention comprises too little abrasive, the composition may not exhibit sufficient removal rate. In contrast, if the polishing composition comprises too much abrasive then the polishing composition may exhibit undesirable polishing performance and/or may not be cost effective and/or may lack stability. The polishing composition can comprise about 10 wt. % or less of the abrasive, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the abrasive. Alternatively, or in addition, the polishing composition can comprise about 0.001 wt. % or more of the abrasive, for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of abrasive. Thus, the polishing composition can comprise abrasive in an amount bounded by any two of the aforementioned endpoints, as appropriate.

For example, in some embodiments, the abrasive can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the abrasive. In certain embodiments, the polishing composition comprises about 0.1 wt. % to about 5 wt. % of the abrasive.

The polishing composition comprises a polishing promoter compound comprising (i) at least two nitrogen atoms (e.g., two nitrogen atoms, three nitrogen atoms, four nitrogen atoms, five nitrogen atoms, six nitrogen atoms, seven nitrogen atoms, or eight nitrogen atoms, or more) and (ii) at least two chemical moieties (e.g., two chemical moieties, three chemical moieties, four chemical moieties, five chemical moieties, six chemical moieties, seven chemical moieties, or eight chemical moieties, or more) selected from a phosphonic acid, a carboxylic acid, an alcohol, an anhydride, and a combination thereof. In some embodiments, the polishing promoter compound comprises (i) at least two nitrogen atoms (e.g., two nitrogen atoms, three nitrogen atoms, four nitrogen atoms, five nitrogen atoms, six nitrogen atoms, seven nitrogen atoms, or eight nitrogen atoms, or more) and (ii) at least four chemical moieties (e.g., two chemical moieties, three chemical moieties, four chemical moieties, five chemical moieties, six chemical moieties, seven chemical moieties, or eight chemical moieties, or more) selected from a phosphonic acid, a carboxylic acid, an alcohol, and a combination thereof and/or at least two anhydride chemical moieties. In certain embodiments, polishing promoter compound comprises at least four valences (e.g., four valences, five valences, six valences, seven valences, eight valences, nine valences, ten valences, eleven valences, or twelve valences, or more) displaced with a chemical moiety selected from a phosphonic acid, a carboxylic acid, an alcohol, an anhydride, and a combination thereof. In that respect, a person of ordinary skill in the art would understand that a phosphonic acid, a carboxylic acid, and an alcohol each correspond to a displacement of a single valence, whereas an anhydride corresponds to a displacement of two valences.

In some embodiments, the polishing promoter compound comprises at least one group selected from —N(CH₂P(O)(OH)₂)₂ group, —N(CH₂CO₂H)₂ group, —N(CH₂CH₂OH)₂ group,

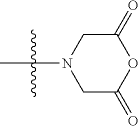 [SMILES: *N1CC(=O)OC(=O)C1]

group, salts thereof, and combinations thereof. In certain embodiments, the polishing promoter compound comprises at least two groups selected from —N(CH₂P(O)(OH)₂)₂ groups, —N(CH₂CO₂H)₂ groups, —N(CH₂CH₂OH)₂ groups,

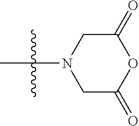 [SMILES: *N1CC(=O)OC(=O)C1]

groups, salts thereof, and combinations thereof. In some embodiments, the polishing promoter compound comprises (i) at least two nitrogen atoms (e.g., two nitrogen atoms, three nitrogen atoms, four nitrogen atoms, five nitrogen atoms, six nitrogen atoms, seven nitrogen atoms, or eight nitrogen atoms, or more) and (ii) at least four (e.g., four, five, six, seven, or eight, or more) phosphonic acid groups (e.g., —N(CH₂P(O)(OH)₂)₂ groups), carboxylic acid groups (e.g., —N(CH₂CO₂H)₂ groups), or alcohol groups (e.g., —N(CH₂CH₂OH)₂ groups). In some embodiments, the polishing promoter compound comprises (i) at least two nitrogen atoms (e.g., two nitrogen atoms, three nitrogen atoms, four nitrogen atoms, five nitrogen atoms, six nitrogen atoms, seven nitrogen atoms, or eight nitrogen atoms, or more) and (ii) at least two (e.g., two, three, four, five, six, seven, or eight, or more) anhydride groups (e.g.,

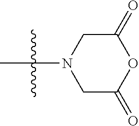 [SMILES: *N1CC(=O)OC(=O)C1]

groups).

Exemplary polishing promoter compounds include, but are not limited to ethylenediaminetetraacetic acid (EDTA), 1,2-cyclohexanediaminetetracetic acid (CyDTA), diethylenetriamine pentaacetic acid (DTPA), ethylenediamine-N,N,N′,N′-tetra-2-propanol (EDTP), ethyleneglycol-bis(β-aminoethyl)-N,N,N′,N′-tetraacetic acid (EGTA), hydroxyethylethylenediaminetriacetic acid (HEDTA), ethylenediamine tetra(methylene phosphonic acid) (EDTMP), N,N′-bis(salicylidene)ethylenediamine, diethylenetriaminepentaacetic dianhydride, ethylenediaminetetraacetic dianhydride, and diethylenetriamine penta(methylene phosphonic acid) (DTPMP), salts thereof, or combinations thereof. In some embodiments, the polishing promoter compound is selected from diethylenetriamine pentaacetic acid (DTPA), ethylenediaminetetraacetic acid (EDTA), hydroxyethylethylenediaminetriacetic acid (HEDTA), salts thereof, and combinations thereof.

The polishing promoter compound can be present in the polishing composition in any suitable amount. For example, the polishing composition can comprise about 10 wt. % or less of the polishing promoter compound, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, or about 1 wt. % or less of the polishing promoter compound. Alternatively, or in addition, the polishing composition can comprise about 0.001 wt. % or more of the polishing promoter compound, for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the polishing promoter compound. Thus, the polishing composition can comprise the polishing promoter compound in an amount bounded by any two of the aforementioned endpoints, as appropriate.

For example, in some embodiments, the polishing promoter compound can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.1 wt. % to about 10 wt. % of the polishing promoter compound. In certain embodiments, the polishing composition comprises about 1 wt. % to about 5 wt. % of the polishing promoter compound.

The polishing composition comprises a topography control agent comprising a nonionic polymer, an anionic polymer, or a combination thereof. The topography control agent can be any suitable nonionic polymer, anionic polymer, or a combination thereof. For example, the topography control agent can be a homopolymer or a copolymer. In embodiments where the topography control agent is a copolymer, the copolymer can be any suitable copolymer. For example, the copolymer can be a random copolymer, a block copolymer, a graft copolymer, or an alternating copolymer.

In some embodiments, the topography control agent comprises polyvinylalcohol (PVA), glycerin, polyethyeneglycol (PEG), polypropyleneglycol (PPG), a copolymer of ethylene glycol and propylene glycol, polyvinylpyrrolidon (PVP), poly(meth)acrylic acid, poly(meth)acrylamide, polyallylamine, a copolymer of (meth)acrylic acid and hydroxypropyl (meth)acrylate, a copolymer of (meth)acrylic acid and maleic acid, a salt thereof, or a combination thereof. In certain embodiments, the topography control agent is selected from polyethyeneglycol (PEG), polypropyleneglycol (PPG), a copolymer of ethylene glycol and propylene glycol, poly(meth)acrylic acid, poly(meth)acrylamide, polyallylamine, salts thereof, and combinations thereof.

The topography control agent can have any suitable weight average molecular weight. The topography control agent can have a weight average molecular weight of about 400 g/mol or more, for example, about 500 g/mol or more, about 1,000 g/mol or more, about 5,000 g/mol or more, about 10,000 g/mol or more, about 20,000 g/mol or more, about 30,000 g/mol or more, about 40,000 g/mol or more, about 50,000 g/mol or more, about 60,000 g/mol or more, about 70,000 g/mol or more, about 80,000 g/mol or more, about 90,000 g/mol or more, about 100,000 g/mol or more, about 110,000 g/mol or more, about 120,000 g/mol or more, about 130,000 g/mol or more, about 140,000 g/mol or more, or about 150,000 g/mol or more. Alternatively, or in addition, the topography control agent can have a weight average molecular weight of about 1,000,000 g/mol or less, for example, about 500,000 g/mol or less, about 200,000 g/mol or less, about 190,000 g/mol or less, about 180,000 g/mol or less, about 175,000 g/mol or less, about 170,000 g/mol or less, about 165,000 g/mol or less, about 160,000 g/mol or less, about 155,000 g/mol or less, or about 150,000 g/mol or less.

Thus, the topography control agent can have a weight average molecular weight bounded by any two of the aforementioned endpoints. For example, the topography control agent can have a weight average molecular weight of about 400 g/mol to about 1,000,000 g/mol, about 1,000 g/mol to about 1,000,000 g/mol, about 5,000 g/mol to about 1,000,000 g/mol, about 10,000 g/mol to about 1,000,000 g/mol, about 20,000 g/mol to about 1,000,000 g/mol, about 50,000 g/mol to about 1,000,000 g/mol, about 60,000 g/mol to about 1,000,000 g/mol, about 70,000 g/mol to about 1,000,000 g/mol, about 75,000 g/mol to about 1,000,000 g/mol, about 80,000 g/mol to about 1,000,000 g/mol, about 90,000 g/mol to about 1,000,000 g/mol, about 400 g/mol to about 500,000 g/mol, 1,000 g/mol to about 500,000 g/mol, about 5,000 g/mol to about 500,000 g/mol, about 10,000 g/mol to about 500,000 g/mol, about 20,000 g/mol to about 500,000 g/mol, about 50,000 g/mol to about 500,000 g/mol, about 60,000 g/mol to about 500,000 g/mol, about 70,000 g/mol to about 500,000 g/mol, about 75,000 g/mol to about 500,000 g/mol, about 80,000 g/mol to about 500,000 g/mol, about 90,000 g/mol to about 200,000 g/mol, about 400 g/mol to about 200,000 g/mol, 1,000 g/mol to about 200,000 g/mol, about 5,000 g/mol to about 200,000 g/mol, about 10,000 g/mol to about 200,000 g/mol, about 20,000 g/mol to about 200,000 g/mol, about 50,000 g/mol to about 200,000 g/mol, about 60,000 g/mol to about 200,000 g/mol, about 70,000 g/mol to about 200,000 g/mol, about 75,000 g/mol to about 200,000 g/mol, about 80,000 g/mol to about 200,000 g/mol, about 90,000 g/mol to about 200,000 g/mol, about 400 g/mol to about 150,000 g/mol, about 1,000 g/mol to about 150,000 g/mol, about 5,000 g/mol to about 150,000 g/mol, about 10,000 g/mol to about 150,000 g/mol, about 20,000 g/mol to about 150,000 g/mol, about 50,000 g/mol to about 150,000 g/mol, about 60,000 g/mol to about 150,000 g/mol, about 70,000 g/mol to about 150,000 g/mol, about 75,000 g/mol to about 150,000 g/mol, about 80,000 g/mol to about 150,000 g/mol, about 90,000 g/mol to about 150,000 g/mol, about 400 g/mol to about 100,000 g/mol, about 1,000 g/mol to about 100,000 g/mol, about 5,000 g/mol to about 100,000 g/mol, about 10,000 g/mol to about 100,000 g/mol, about 20,000 g/mol to about 100,000 g/mol, or about 50,000 g/mol to about 100,000 g/mol.

The chemical-mechanical polishing composition can comprise any suitable amount of the topography control agent. The amount of the topography control agent refers to the total amount of nonionic polymer and/or anionic polymer present in the polishing composition. The polishing composition can comprise about 10 ppm or more of the topography control agent, for example, about 50 ppm or more, about 100 ppm or more, about 200 ppm or more, about 300 ppm or more, about 400 ppm or more, or about 500 ppm or more. Alternatively, or in addition, the polishing composition can comprise about 10000 ppm or less of the topography control agent, for example, about 7500 ppm or less, about 5000 ppm or less, about 4000 ppm or less, about 3000 ppm or less, about 2000 ppm or less, or about 1000 ppm or less.

Thus, the polishing composition can comprise the topography control agent in an amount bounded by any two of the aforementioned endpoints. For example, the polishing composition can comprise about 10 ppm to about 10000 ppm of the topography control agent, e.g., about 50 ppm to about 10000 ppm, about 100 ppm to about 10000 ppm, about 200 ppm to about 10000 ppm, about 300 ppm to about 10000 ppm, about 400 ppm to about 10000 ppm, about 500 ppm to about 10000 ppm, about 10 ppm to about 7500 ppm, about 50 ppm to about 7500 ppm, about 100 ppm to about 7500 ppm, about 200 ppm to about 7500 ppm, about 300 ppm to about 7500 ppm, about 400 ppm to about 7500 ppm, about 500 ppm to about 7500 ppm, about 10 ppm to about 5000 ppm, about 50 ppm to about 5000 ppm, about 100 ppm to about 5000 ppm, about 200 ppm to about 5000 ppm, about 300 ppm to about 5000 ppm, about 400 ppm to about 5000 ppm, about 500 ppm to about 5000 ppm, about 10 ppm to about 3000 ppm, about 50 ppm to about 3000 ppm, about 100 ppm to about 3000 ppm, about 200 ppm to about 3000 ppm, about 300 ppm to about 3000 ppm, about 400 ppm to about 3000 ppm, or about 500 ppm to about 3000 ppm. In some embodiments, the polishing composition comprises about 100 ppm to about 5000 ppm of the topography control agent. In certain embodiments, the polishing composition comprises about 500 ppm to about 3000 ppm of the topography control agent.

The polishing composition comprises a corrosion inhibitor. The corrosion inhibitor can be any suitable small molecule (i.e., less than 500 g/mol) capable of inhibiting corrosion of a substrate surface (e.g., silver surface). In some embodiments, the corrosion inhibitor is a small molecule comprising an azole (e.g., an azole, a diazole, or a triazole) group and/or a nitrile group. For example, the corrosion inhibitor can be 1H-1,2,3-triazolo[4,5-b]pyridine (TAP), 1,2,3-benzotriazole (BTA), adenosine, adenine, dicyandiamide, 1,2,4-triazole (TAZ), 1H-1,2,3-triazole, 3-amino-1,2,4-triazole (ATA), pyrimidine, 1,2,4-trizaole-3-thiol, tolyltriazole, a salt thereof, or a combination thereof. In some embodiments, the corrosion inhibitor comprises 1H-1,2,3-triazolo[4,5-b]pyridine (TAP) or a salt thereof.

The chemical-mechanical polishing composition can comprise any suitable amount of the corrosion inhibitor. The polishing composition can comprise about 10 ppm or more of the corrosion inhibitor, for example, about 50 ppm or more, about 100 ppm or more, about 200 ppm or more, about 300 ppm or more, about 400 ppm or more, or about 500 ppm or more. Alternatively, or in addition, the polishing composition can comprise about 10000 ppm or less of the corrosion inhibitor, for example, about 7500 ppm or less, about 5000 ppm or less, about 4000 ppm or less, about 3000 ppm or less, about 2000 ppm or less, or about 1000 ppm or less.

Thus, the polishing composition can comprise the corrosion inhibitor in an amount bounded by any two of the aforementioned endpoints. For example, the polishing composition can comprise about 10 ppm to about 10000 ppm of the corrosion inhibitor, e.g., about 50 ppm to about 10000 ppm, about 100 ppm to about 10000 ppm, about 200 ppm to about 10000 ppm, about 300 ppm to about 10000 ppm, about 400 ppm to about 10000 ppm, about 500 ppm to about 10000 ppm, about 10 ppm to about 7500 ppm, about 50 ppm to about 7500 ppm, about 100 ppm to about 7500 ppm, about 200 ppm to about 7500 ppm, about 300 ppm to about 7500 ppm, about 400 ppm to about 7500 ppm, about 500 ppm to about 7500 ppm, about 10 ppm to about 5000 ppm, about 50 ppm to about 5000 ppm, about 100 ppm to about 5000 ppm, about 200 ppm to about 5000 ppm, about 300 ppm to about 5000 ppm, about 400 ppm to about 5000 ppm, about 500 ppm to about 5000 ppm, about 10 ppm to about 3000 ppm, about 50 ppm to about 3000 ppm, about 100 ppm to about 3000 ppm, about 200 ppm to about 3000 ppm, about 300 ppm to about 3000 ppm, about 400 ppm to about 3000 ppm, or about 500 ppm to about 3000 ppm. In some embodiments, the polishing composition comprises about 100 ppm to about 5000 ppm of the corrosion inhibitor. In certain embodiments, the polishing composition comprises about 500 ppm to about 3000 ppm of the corrosion inhibitor.

The chemical-mechanical polishing composition comprises water. The water can be any suitable water including, for example, deionized water or distilled water. In some embodiments, the chemical-mechanical polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like. In certain embodiments, the chemical-mechanical polishing composition comprises pure water.

The chemical-mechanical polishing can have any suitable pH at the point-of-use. Thus, the chemical-mechanical polishing composition can have a pH of about 1 or more, e.g., about 1.5 or more, about 2 or more, about 2.5 or more, about 3 or more, about 3.5 or more, about 4 or more, about 4.5 or more, about 5 or more, about 5.5 or more, about 6 or more, about 6.5 or more, or about 7 or more. Alternatively, or in addition, the chemical-mechanical polishing composition can have a pH of about 14 or less, e.g., about 13.5 or less, about 13 or less, about 12.5 or less, about 12 or less, about 11.5 or less, about 11 or less, about 10.5 or less, about 10 or less, about 9.5 or less, or about 9 or less. Thus, the chemical-mechanical polishing composition can have a pH bounded by any two of the aforementioned endpoints. For example the chemical-mechanical polishing composition can have a pH of about 2 to about 12, e.g., about 2 to about 11, about 2 to about 10, about 2 to about 9, about 3 to about 12, about 3 to about 11, about 3 to about 10, about 3 to about 9, about 5 to about 12, about 5 to about 11, about 5 to about 10, about 5 to about 9, about 7 to about 12, about 7 to about 11, about 7 to about 10, or about 7 to about 9 at the point-of-use. In some embodiments, the polishing composition has a pH of about 2 to about 10 at the point-of-use. In certain embodiments, the polishing composition has a pH of about 7 to about 9 at the point-of-use.

The chemical-mechanical polishing composition can comprise one or more compounds capable of adjusting (i.e., that adjust) the pH of the polishing composition (i.e., pH-adjusting agent). The pH of the polishing composition can be adjusted using any suitable compound capable of adjusting the pH of the polishing composition. The pH-adjusting agent desirably is water-soluble and compatible with the other components of the polishing composition. Non-limiting examples of suitable acids for adjusting the pH of the polishing composition include nitric acid, sulfuric acid, phosphoric acid, and organic acids such as formic acid and acetic acid. Non-limiting examples of suitable bases for adjusting the pH of the polishing composition include sodium hydroxide, potassium hydroxide, and ammonium hydroxide.

In some embodiments, the chemical-mechanical polishing composition further comprises an oxidizing agent. The oxidizing agent can be any suitable oxidizing agent. Non-limiting examples of suitable oxidizing agents includes oxone, cerium ammonium nitrate, a peroxide (e.g., hydrogen peroxide), a periodate (e.g., sodium periodate or potassium periodate), an iodate (e.g., sodium iodate, potassium iodate, or ammonium iodate), a persulfate (e.g., sodium persulfate, potassium persulfate, or ammonium persulfate), a chlorate (e.g., sodium chlorate or potassium chlorate), a chromate (e.g., sodium chromate or potassium chromate), a permanganate (e.g., sodium permanganate, potassium permanganate, or ammonium permanganate), a bromate (e.g., sodium bromate or potassium bromate), a perbromate (e.g., sodium perbromate or potassium perbromate), a ferrate (e.g., potassium ferrate), a perrhenate (e.g., ammonium perrhenate), a perruthenate (e.g., tetrapropylammonium perruthenate), and a combination thereof. In some embodiments, the oxidizing agent is hydrogen peroxide. The polishing composition can comprise any suitable amount of the oxidizing agent. For example, the polishing composition can comprise about 0.01 wt. % to about 5 wt. % of the oxidizing agent (e.g., 0.01 wt. % to about 3 wt. %, 0.1 wt. % to about 5 wt. %, 0.1 wt. % to about 3 wt. %, about 0.5 wt. % to about 5 wt. %, about 0.5 wt. % to about 3 wt. %, or about 0.01 wt. % to about 1 wt. % of the oxidizing agent).

In some embodiments, the composition further comprises a biocide, a conductivity adjustor, or a combination thereof. A biocide, when present, can be any suitable biocide and can be present in the polishing composition in any suitable amount. A suitable biocide is an isothiazolinone biocide. Typically, the polishing composition comprises about 1 ppm to about 500 ppm biocide (e.g., about 1 ppm to about 200 ppm or about 10 ppm to about 200 ppm), preferably about 10 ppm to about 200 ppm biocide.

In some embodiments, the chemical-mechanical polishing composition further comprises one or more additives such as, for example, conditioners, acids (e.g., sulfonic acids), scale inhibitors, dispersants, and/or conductivity adjustors.

The polishing composition can be produced by any suitable technique, many of which are known to those skilled in the art. The polishing composition can be prepared in a batch or continuous process. Generally, the polishing composition is prepared by combining the components of the polishing composition in any order. The term “component” as used herein includes individual ingredients (e.g., abrasive, polishing promoter compound, topography control agent, corrosion inhibitor, and/or any other optional additive, etc.) as well as any combination of ingredients (e.g., abrasive, polishing promoter compound, topography control agent, corrosion inhibitor, and/or any other optional additive, etc.).

For example, the polishing composition can be prepared by (i) providing all or a portion of the liquid carrier, (ii) dispersing the abrasive, polishing promoter compound, topography control agent, corrosion inhibitor, and/or any other optional additive, etc., using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., polishing promoter compound, topography control agent, corrosion inhibitor, and/or any other optional additive, etc.) in an abrasive slurry, (ii) providing one or more components in an additive solution (e.g., polishing promoter compound, topography control agent, corrosion inhibitor, and/or any other optional additive, etc.), (iii) combining the abrasive slurry and the additive solution to form a mixture, (iv) optionally adding suitable amounts of any other optional additives to the mixture, and (v) adjusting the pH of the mixture as appropriate.

The polishing composition can be supplied as a one-package system comprising an abrasive, polishing promoter compound, topography control agent, corrosion inhibitor, and/or any other optional additive, and water. Alternatively, the polishing composition of the invention can be supplied as a two-package system comprising an abrasive slurry in a first package and an additive solution in a second package, wherein the abrasive slurry consists essentially of, or consists of, an abrasive, and water, and wherein the additive solution consists essentially of, or consists of, the polishing promoter compound, topography control agent, corrosion inhibitor, and/or any other optional additive. The two-package system allows for the adjustment of polishing composition characteristics by changing the blending ratio of the two packages, i.e., the abrasive slurry and the additive solution.

Various methods can be employed to utilize such a two-package polishing system. For example, the abrasive slurry and additive solution can be delivered to the polishing table by different pipes that are joined and connected at the outlet of supply piping. The abrasive slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 10 minutes or less prior to being added in mixed form onto the platen, for example, about 5 minutes or less, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 meters of the point-of-use, such as within 1 meter of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high-pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the polishing promoter compound, topography control agent, corrosion inhibitor, and/or any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that the abrasive, polishing promoter compound, topography control agent, corrosion inhibitor, and/or any other optional additive are at least partially or fully dissolved in the concentrate.

The invention further provides a method of chemically-mechanically polishing a substrate comprising: (i) providing a substrate, (ii) providing a polishing pad, (iii) providing a chemical-mechanical polishing composition comprising: (a) an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (c) water, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of silver. Suitable substrates include wafers used in the semiconductor industry. The wafers typically comprise or consist of, for example, a metal, metal oxide, metal nitride, metal composite, metal alloy, a low dielectric material, or combinations thereof. The method of the invention is particularly useful for polishing substrates comprising silver. Thus, in some embodiments, the substrate comprises silver on a surface of the substrate, and at least a portion of the silver on the surface of the substrate is abraded at a removal rate (Å/min) to polish the substrate.

In particular, in some embodiments, the invention provides a method of chemically-mechanically polishing a substrate comprising: (i) providing a substrate, wherein the substrate comprises silver on a surface of the substrate, (ii) providing a polishing pad, (iii) providing a chemical-mechanical polishing composition comprising: (a) an abrasive selected from a silica abrasive, an alumina abrasive, and a combination thereof, (b) a polishing promoter compound comprising (i) at least two nitrogen atoms and (ii) at least two chemical moieties selected from a phosphonic acid, a carboxylic acid, an alcohol, an anhydride, and a combination thereof, (c) a topography control agent comprising a nonionic polymer, an anionic polymer, or a combination thereof, (d) a corrosion inhibitor, and (c) water, (iv) contacting the substrate with the polishing pad and the chemical-mechanical polishing composition, and (v) moving the polishing pad and the chemical-mechanical polishing composition relative to the substrate to abrade at least a portion of the silver on a surface of the substrate to polish the substrate

The method comprises contacting the substrate with the polishing pad and the chemical-mechanical polishing composition. The substrate can be contacted with the polishing pad with any suitable downforce. For example, the substrate can be contacted with the polishing pad at a downforce of about 1 kPa or more, e.g., about 2 kPa or more, about 3 kPa or more, about 4 kPa or more, about 5 kPa or more, about 6 kPa or more, about 7 kPa or more, about 8 kPa or more, about 9 kPa or more, or about 10 or more. Alternatively, or in addition, the substrate can be contacted with the polishing pad at a downforce of about 100 kPa or less, e.g., about 50 kPa or less, about 30 kPa or less, about 20 kPa or less, or about 10 kPa or less. Thus, the substrate can be contacted with the polishing pad with any downforce bounded by any two of the aforementioned endpoints. For example the substrate can be contacted with the polishing pad with a downforce of about 1 kPa to about 100 kPa, e.g., about 1 kPa to about 50 kPa, about 1 kPa to about 30 kPa, about 1 kPa to about 20 kPa, about 1 kPa to about 10 kPa, about 2 kPa to about 100 kPa, about 2 kPa to about 50 kPa, about 2 kPa to about 30 kPa, about 2 kPa to about 20 kPa, about 2 kPa to about 10 kPa, about 3 kPa to about 100 kPa, about 3 kPa to about 50 kPa, about 3 kPa to about 30 kPa, about 3 kPa to about 20 kPa, about 3 kPa to about 10 kPa, about 4 kPa to about 100 kPa, about 4 kPa to about 50 kPa, about 4 kPa to about 30 kPa, about 4 kPa to about 20 kPa, about 4 kPa to about 10 kPa, about 5 kPa to about 100 kPa, about 5 kPa to about 50 kPa, about 5 kPa to about 30 kPa, about 5 kPa to about 20 kPa, about 5 kPa to about 10 kPa, about 10 kPa to about 100 kPa, about 10 kPa to about 50 kPa, about 10 kPa to about 30 kPa, or about 10 kPa to about 20 kPa. In some embodiments, the substrate is contacted with the polishing pad at a downforce of about 5 kPa to about 50 kPa. In some embodiments, the substrate is contacted with the polishing pad at a downforce of about 5 kPa to about 30 kPa. In certain embodiments, the substrate is contacted with the polishing pad at a downforce of about 10 kPa to about 20 kPa.

The chemical-mechanical polishing composition of the invention desirably exhibits a high removal rate when polishing a substrate comprising silver according to a method of the invention. For example, when polishing substrates comprising silver in accordance with an embodiment of the invention, the polishing composition desirably exhibits a removal rate of the silver of about 1200 Å/min or higher, for example, about 1500 Å/min or higher, about 1600 Å/min or higher, about 1700 Å/min or higher, about 1800 Å/min or higher, about 1900 Å/min or higher, or about 2,000 Å/min or higher.

The polishing composition of the invention desirably exhibits low particle defects when polishing a substrate, as determined by suitable techniques. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SP1 instruments operating at a 120 nm threshold or at 160 nm threshold).

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 (commercially available from, for example, Eminess Technologies), POLITEX™, EPIC™ D100 pad (commercially available from Cabot Microelectronics), IC1010 pad (commercially available from Dow, Inc.) and Fujibo POLYPAS™ 27.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511. 5,643,046, 5,658,183, 5,730,642, 5,838,447, 5,872,633. 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

Aspects, including embodiments, of the invention described herein may be beneficial alone or in combination, with one or more other aspects or embodiments. Without limiting the foregoing description, certain non-limiting embodiments of the disclosure numbered 1-48 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a chemical-mechanical polishing composition comprising:
(a) an abrasive selected from a silica abrasive, an alumina abrasive, and a combination thereof,
(b) a polishing promoter compound comprising (i) at least two nitrogen atoms and (ii) at least two chemical moieties selected from a phosphonic acid, a carboxylic acid, an alcohol, an anhydride, and a combination thereof,
(c) a topography control agent comprising a nonionic polymer, an anionic polymer, or a combination thereof,
(d) a corrosion inhibitor, and
(e) water.
(2) In embodiment (2) is presented the polishing composition of embodiment (1), wherein the polishing composition comprises about 0.001 wt. % to about 10 wt. % of the abrasive.
(3) In embodiment (3) is presented the polishing composition of embodiment (1) or embodiment (2), wherein the polishing composition comprises about 0.1 wt. % to about 5 wt. % of the abrasive.
(4) In embodiment (4) is presented the polishing composition of any one of embodiments (1)-(3), wherein the abrasive is a colloidal abrasive.
(5) In embodiment (5) is presented the polishing composition of any one of embodiments (1)-(4), wherein the polishing composition has a pH of about 2 to about 10.
(6) In embodiment (6) is presented the polishing composition of any one of embodiments (1)-(5), wherein the polishing composition has a pH of about 7 to about 9.
(7) In embodiment (7) is presented the polishing composition of any one of embodiments (1)-(6), wherein the polishing promoter compound comprises at least one group selected from —N(CH₂P(O)(OH)₂)₂ group, —N(CH₂CO₂H)₂ group, —N(CH₂CH₂OH)₂ group,

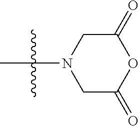 [SMILES: *N1CC(=O)OC(=O)C1]

group, salts thereof, and combinations thereof.
(8) In embodiment (8) is presented the polishing composition of any one of embodiments (1)-(7), wherein the polishing promoter compound comprises at least two groups selected from —N(CH₂P(O)(OH)₂)₂ groups, —N(CH₂CO₂H)₂ groups, —N(CH₂CH₂OH)₂ groups,

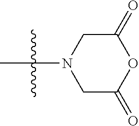 [SMILES: *N1CC(=O)OC(=O)C1]

groups, salts thereof, and combinations thereof.
(9) In embodiment (9) is presented the polishing composition of any one of embodiments (1)-(8), wherein the polishing promoter compound is selected from ethylenediaminetetraacetic acid (EDTA), 1,2-cyclohexanediaminetetracetic acid (CyDTA), diethylenetriamine pentaacetic acid (DTPA), ethylenediamine-N,N,N′,N′-tetra-2-propanol (EDTP), ethyleneglycol-bis(β-aminoethyl)-N,N,N′,N′-tetraacetic acid (EGTA), hydroxyethylethylenediaminetriacetic acid (HEDTA), ethylenediamine tetra(methylene phosphonic acid) (EDTMP), N,N′-bis(salicylidene)ethylenediamine, diethylenetriaminepentaacetic dianhydride, ethylenediaminetetraacetic dianhydride, diethylenetriamine penta(methylene phosphonic acid) (DTPMP), salts thereof, and combinations thereof.
(10) In embodiment (10) is presented the polishing composition of any one of embodiments (1)-(9), wherein the polishing promoter compound is selected from diethylenetriamine pentaacetic acid (DTPA), ethylenediaminetetraacetic acid (EDTA), hydroxyethylethylenediaminetriacetic acid (HEDTA), salts thereof, and combinations thereof.
(11) In embodiment (11) is presented the polishing composition of any one of embodiments (1)-(10), wherein the polishing composition comprises about 0.1 wt. % to about 10 wt. % of the polishing promoter compound.
(12) In embodiment (12) is presented the polishing composition of any one of embodiments (1)-(11), wherein the polishing composition comprises about 1 wt. % to about 5 wt. % of the polishing promoter compound.
(13) In embodiment (13) is presented the polishing composition of any one of embodiments (1)-(12), wherein the topography control agent comprises polyvinylalcohol (PVA), glycerin, polyethyeneglycol (PEG), polypropyleneglycol (PPG), a copolymer of ethylene glycol and propylene glycol, polyvinylpyrrolidon (PVP), poly(meth)acrylic acid, poly(meth)acrylamide, polyallylamine, a copolymer of (meth)acrylic acid and hydroxypropyl (meth)acrylate, a copolymer of (meth)acrylic acid and maleic acid, a salt thereof, or a combination thereof.
(14) In embodiment (14) is presented the polishing composition of any one of embodiments (1)-(13), wherein the topography control agent is selected from polyethyeneglycol (PEG), polypropyleneglycol (PPG), a copolymer of ethylene glycol and propylene glycol, poly(meth)acrylic acid, poly(meth)acrylamide, polyallylamine, salts thereof, and combinations thereof.
(15) In embodiment (15) is presented the polishing composition of any one of embodiments (1)-(14), wherein the polishing composition comprises about 100 ppm to about 5000 ppm of the topography control agent.
(16) In embodiment (16) is presented the polishing composition of any one of embodiments (1)-(15), wherein the polishing composition comprises about 500 ppm to about 3000 ppm of the topography control agent.
(17) In embodiment (17) is presented the polishing composition of any one of embodiments (1)-(16), wherein the corrosion inhibitor is selected from 1H-1,2,3-triazolo[4,5-b]pyridine (TAP), 1,2,3-benzotriazole (BTA), adenosine, adenine, dicyandiamide, 1,2,4-triazole (TAZ), 1H-1,2,3-triazole, 3-amino-1,2,4-triazole (ATA), pyrimidine, 1,2,4-trizaole-3-thiol, tolyltriazole, salts thereof, and combinations thereof.
(18) In embodiment (18) is presented the polishing composition of any one of embodiments (1)-(17), wherein the corrosion inhibitor comprises 1H-1,2,3-triazolo[4,5-b]pyridine (TAP) or a salt thereof.
(19) In embodiment (19) is presented the polishing composition of any one of embodiments (1)-(18), wherein the polishing composition comprises about 100 ppm to about 5000 ppm of the corrosion inhibitor.
(20) In embodiment (20) is presented the polishing composition of any one of embodiments (1)-(19), wherein the polishing composition comprises about 500 ppm to about 3000 ppm of the corrosion inhibitor.
(21) In embodiment (21) is presented the polishing composition of any one of embodiments (1)-(20), wherein the polishing composition further comprises a pH-adjusting agent.
(22) In embodiment (22) is presented the polishing composition of any one of embodiments (1)-(21), wherein the polishing composition further comprises a biocide.
(23) In embodiment (23) is presented a method of chemically-mechanically polishing a substrate comprising:
(i) providing a substrate,
(ii) providing a polishing pad,
(iii) providing a chemical-mechanical polishing composition comprising:
   (a) an abrasive selected from a silica abrasive, an alumina abrasive, and a combination thereof,
   (b) a polishing promoter compound comprising (i) at least two nitrogen atoms and (ii) at least two chemical moieties selected from a phosphonic acid, a carboxylic acid, an alcohol, an anhydride, and a combination thereof,
   (c) a topography control agent comprising a nonionic polymer, an anionic polymer, or a combination thereof,
   (d) a corrosion inhibitor, and
   (e) water,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.
(24) In embodiment (24) is presented the method of embodiment (23), wherein the polishing composition comprises about 0.001 wt. % to about 10 wt. % of the abrasive.
(25) In embodiment (25) is presented the method of embodiment (23) or embodiment (24), wherein the polishing composition comprises about 0.1 wt. % to about 5 wt. % of the abrasive.
(26) In embodiment (26) is presented the method of any one of embodiments (23)-(25), wherein the abrasive is a colloidal abrasive.
(27) In embodiment (27) is presented the method of any one of embodiments (23)-(26), wherein the polishing composition has a pH of about 2 to about 10.
(28) In embodiment (28) is presented the method of any one of embodiments (23)-(27), wherein the polishing composition has a pH of about 7 to about 9.
(29) In embodiment (29) is presented the method of any one of embodiments (23)-(28), wherein the polishing promoter compound comprises at least one group selected from —N(CH₂P(O)(OH)₂)₂ group, —N(CH₂CO₂H)₂ group, —N(CH₂CH₂OH)₂ group,

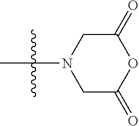 [SMILES: *N1CC(=O)OC(=O)C1]

group, salts thereof, and combinations thereof.
(30) In embodiment (30) is presented the method of any one of embodiments (23)-(29), wherein the polishing promoter compound comprises at least two groups selected from —N(CH₂P(O)(OH)₂)₂ groups, —N(CH₂CO₂H)₂ groups, —N(CH₂CH₂OH)₂ groups,

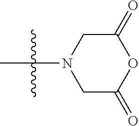 [SMILES: *N1CC(=O)OC(=O)C1]

groups, salts thereof, and combinations thereof.
(31) In embodiment (31) is presented the method of any one of embodiments (23)-(30), wherein the polishing promoter compound is selected from ethylenediaminetetraacetic acid (EDTA), 1,2-cyclohexanediaminetetracetic acid (CyDTA), diethylenetriamine pentaacetic acid (DTPA), ethylenediamine-N,N,N′,N′-tetra-2-propanol (EDTP), ethyleneglycol-bis(β-aminoethyl)-N,N,N′,N′-tetraacetic acid (EGTA), hydroxyethylethylenediaminetriacetic acid (HEDTA), ethylenediamine tetra(methylene phosphonic acid) (EDTMP), N,N′-bis(salicylidene)ethylenediamine, diethylenetriaminepentaacetic dianhydride, ethylenediaminetetraacetic dianhydride, diethylenetriamine penta(methylene phosphonic acid) (DTPMP), salts thereof, and combinations thereof.
(32) In embodiment (32) is presented the method of any one of embodiments (23)-(31), wherein the polishing promoter compound is selected from diethylenetriamine pentaacetic acid (DTPA), ethylenediaminetetraacetic acid (EDTA), hydroxyethylethylenediaminetriacetic acid (HEDTA), salts thereof, and combinations thereof.
(33) In embodiment (33) is presented the method of any one of embodiments (23)-(32), wherein the polishing composition comprises about 0.1 wt. % to about 10 wt. % of the polishing promoter compound.
(34) In embodiment (34) is presented the method of any one of embodiments (23)-(33), wherein the polishing composition comprises about 1 wt. % to about 5 wt. % of the polishing promoter compound.
(35) In embodiment (35) is presented the method of any one of embodiments (23)-(34), wherein the topography control agent comprises polyvinylalcohol (PVA), glycerin, polyethyeneglycol (PEG), polypropyleneglycol (PPG), a copolymer of ethylene glycol and propylene glycol, polyvinylpyrrolidon (PVP), poly(meth)acrylic acid, poly(meth)acrylamide, polyallylamine, a copolymer of (meth)acrylic acid and hydroxypropyl (meth)acrylate, a copolymer of (meth)acrylic acid and maleic acid, a salt thereof, or a combination thereof.
(36) In embodiment (36) is presented the method of any one of embodiments (23)-(35), wherein the topography control agent is selected from polyethyeneglycol (PEG), polypropyleneglycol (PPG), a copolymer of ethylene glycol and propylene glycol, poly(meth)acrylic acid, poly(meth)acrylamide, polyallylamine, salts thereof, and combinations thereof.
(37) In embodiment (37) is presented the method of any one of embodiments (23)-(36), wherein the polishing composition comprises about 100 ppm to about 5000 ppm of the topography control agent.
(38) In embodiment (38) is presented the method of any one of embodiments (23)-(37), wherein the polishing composition comprises about 500 ppm to about 3000 ppm of the topography control agent.
(39) In embodiment (39) is presented the method of any one of embodiments (23)-(38), wherein the corrosion inhibitor is selected from 1H-1,2,3-triazolo[4,5-b]pyridine (TAP), 1,2,3-benzotriazole (BTA), adenosine, adenine, dicyandiamide, 1,2,4-triazole (TAZ), 1H-1,2,3-triazole, 3-amino-1,2,4-triazole (ATA), pyrimidine, 1,2,4-trizaole-3-thiol, tolyltriazole, salts thereof, and combinations thereof.
(40) In embodiment (40) is presented the method of any one of embodiments (23)-(39), wherein the corrosion inhibitor comprises 1H-1,2,3-triazolo[4,5-b]pyridine (TAP) or a salt thereof.
(41) In embodiment (41) is presented the method of any one of embodiments (23)-(40), wherein the polishing composition comprises about 100 ppm to about 5000 ppm of the corrosion inhibitor.
(42) In embodiment (42) is presented the method of any one of embodiments (23)-(41), wherein the polishing composition comprises about 500 ppm to about 3000 ppm of the corrosion inhibitor.
(43) In embodiment (43) is presented the method of any one of embodiments (23)-(42), wherein the polishing composition further comprises a pH-adjusting agent.
(44) In embodiment (44) is presented the method of any one of embodiments (23)-(43), wherein the polishing composition further comprises a biocide.
(45) In embodiment (45) is presented the method of any one of embodiments (23)-(44), wherein the substrate comprises silver on a surface of the substrate, and wherein at least a portion of the silver on the surface of the substrate is abraded at a removal rate (Å/min) to polish the substrate.
(46) In embodiment (46) is presented the method of any one of embodiments (23)-(45), wherein the substrate is contacted with the polishing pad at a downforce of about 5 kPa to about 50 kPa.
(47) In embodiment (47) is presented the method of any one of embodiments (23)-(46), wherein the substrate is contacted with the polishing pad at a downforce of about 5 kPa to about 30 kPa.
(48) In embodiment (48) is presented the method of any one of embodiments (23)-(47), wherein the substrate is contacted with the polishing pad at a downforce of about 10 kPa to about 20 kPa.

### EXAMPLES

These following examples further illustrate the invention but, of course, should not be construed as in any way limiting its scope.

The following abbreviations are used throughout the Examples: removal rate (RR); downforce (DF); molecular weight (MW); and parts per million (ppm).

### Example 1

This example demonstrates the effect of a polishing promoter on the polishing performance of a polishing composition prepared according to the invention.

Polishing Compositions 1A-1M contained, after 6× dilution at the point-of-use, 0.2 wt. % alumina abrasive, 125 ppm 1H-1,2,3-triazolo[4,5-b]pyridine (TAP) as the corrosion inhibitor, 400 ppm ALCOSPERSE™ 630 polyacrylic acid as the topography control agent, 16.7 ppm of PROXEL™ AQ as the biocide, 0.2 wt. % hydrogen peroxide as the oxidizing agent, and 3000 ppm of the polishing promoter compound set forth in Table 1. The resulting composition was adjusted to a pH of 8 with ammonium hydroxide.

TABLE 1
Silver Removal Rates as a Function of Polishing Promoter Compound

| Polishing | Polishing Promoter | Silver RR (Å/min) | Silver RR (Å/min) |
|---|---|---|---|
| Composition | Compound | at 2 psi DF | at 3 psi DF |
| 1A (Comparative) | 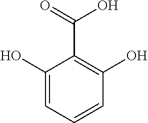 [SMILES: O=C(O)c1c(O)cccc1O] | 423 | 467 |
| 1B (Comparative) | 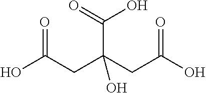 [SMILES: O=C(O)CC(O)(CC(=O)O)C(=O)O] | 702 | 711 |
| 1C (Comparative) | 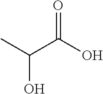 | 728 | 751 |
| 1D (Comparative) | 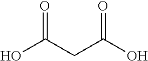 | 772 | 807 |
| 1E (Comparative) | 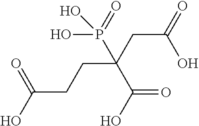 [SMILES: O=C(O)CCC(CC(=O)O)(C(=O)O)P(=O)(O)O] | 823 | 853 |
| 1F (Comparative) | 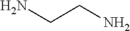 | 948 | 992 |
| 1G (Comparative) | 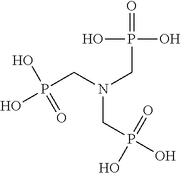 [SMILES: O=P(O)(O)CN(CP(=O)(O)O)CP(=O)(O)O] | 1116 | 1172 |
| 1H (Comparative) | 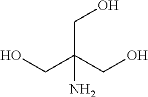 | 1131 | 1233 |
| 1I (Inventive) | 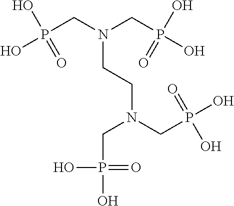 [SMILES: O=P(O)(O)CN(CCN(CP(=O)(O)O)CP(=O)(O)O)CP(=O)(O)O] | 1606 | 1851 |
| | (EDTMP) | | |
| 1J (Comparative) | 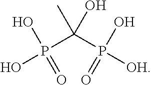 | 1815 | 1964 |
| 1K (Inventive) | 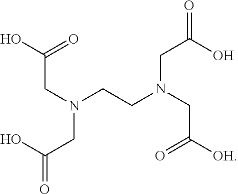 [SMILES: O=C(O)CN(CCN(CC(=O)O)CC(=O)O)CC(=O)O] | 1832 | 1970 |
| | (EDTA) | | |
| 1L (Inventive) | 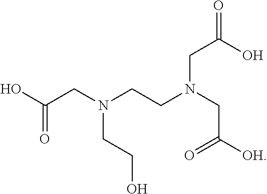 [SMILES: O=C(O)CN(CCO)CCN(CC(=O)O)CC(=O)O] | 1893 | 1950 |
| | (HEDTA) | | |
| 1M (Inventive) | 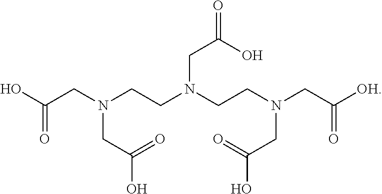 [SMILES: O=C(O)CN(CCN(CC(=O)O)CC(=O)O)CCN(CC(=O)O)CC(=O)O] | 2068 | 2253 |
| | (DTPA) | | |

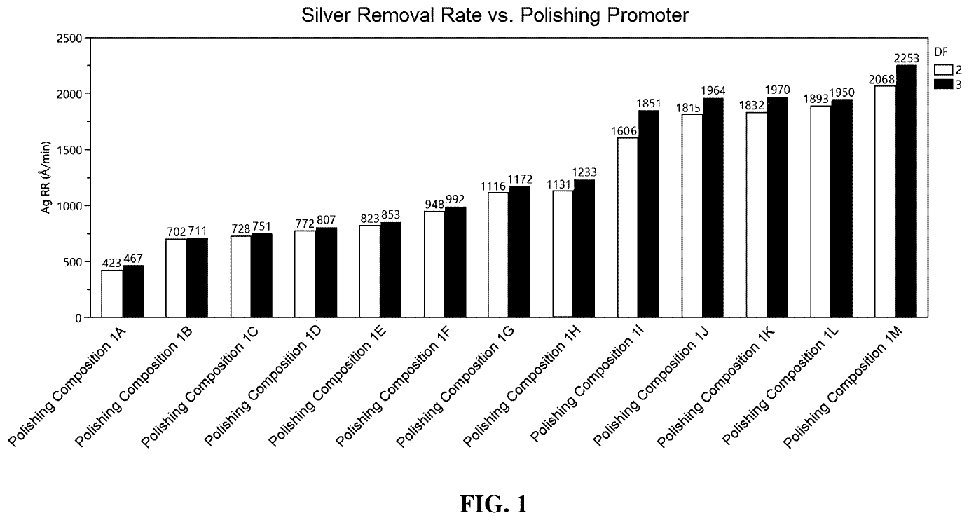

Silver wafers (200 mm) were polished with Polishing Compositions 1A-1M, as set forth in Table 1, using an Applied Materials Mirra polishing machine at 2 psi (13.7 kPA) or 3 psi (20.55 kPa) downforce using a NexPlanar™ U5050 pad (CMC Materials Inc.) conditioned with a product commercially identified as Diamond Pad Conditioner A82 (3M, St. Paul, MN). Mirra polishing parameters were as follows: head speed=87 rpm, platen speed=93 rpm, total flow rate=100 mL/min. All blanket substrates were polished for 20 seconds. Silver removal rates were calculated by measuring the film thickness, using KLA Tencor RS75 resistivity measurement, and subtracting the final thickness from the initial thickness. The results are set forth in Table 1 and FIG. 1.

As is apparent from the results set forth in Table 1 and FIG. 1, inventive Polishing Compositions 1I, 1K, 1L, and 1M, containing a polishing promoter compound comprising (i) at least two nitrogen atoms and (ii) at least two chemical moieties selected from a phosphonic acid, a carboxylic acid, an alcohol, an anhydride, and a combination thereof, exhibited higher silver removal rates than all comparative polishing compositions except comparative Polishing Composition 1J, which contained a polishing promoter compound that was not thermally stable. In addition, the results set forth in Table 1 and FIG. 1 further show that the silver removal rates exhibited by inventive Polishing Compositions 1I, 1K, 1L, and 1M, could be easily tuned by adjusting the downforce of the polishing pad, as evidenced by a noticeable difference between the silver removal rate at a downforce of 2 psi and the silver removal rate at a downforce of 3 psi.

### Example 2

This example demonstrates the effect of a topography control agent on the polishing performance of a polishing composition prepared according to the invention.

Polishing Compositions 2A-2F contained, after 6× dilution at the point-of-use, 0.2 wt. % alumina abrasive, 3000 ppm of diethylenetriamine pentaacetic acid (DTPA) as the polishing promoter compound, 125 ppm 1H-1,2,3-triazolo[4,5-b]pyridine (TAP) as the corrosion inhibitor, 16.7 ppm of PROXEL™ AQ as the biocide, 0.2 wt. % hydrogen peroxide as the oxidizing agent, and 400 ppm of the topography control agent set forth in Table 2. The resulting composition was adjusted to a pH of 8 with ammonium hydroxide.

TABLE 2
Silver Removal Rates as a Function of Topography Control Agent

| | | Silver RR | Silver RR |
|---|---|---|---|
| Polishing | Topography | (Å/min) | (Å/min) |
| Composition | Control Agent | at 2 psi DF | at 3 psi DF |
| 2A | polyethylene glycol | 1026 | 1431 |
| (Inventive) | (MW = 8000 g/mol) | | |
| 2B | polyethylene glycol | 1086 | 1456 |
| (Inventive) | (MW = 100000 g/mol) | | |
| 2C | polypropylene glycol | 1159 | 1511 |
| (Inventive) | (MW = 425 g/mol) | | |
| 2D | polyacrylic acid | 1188 | 1514 |
| (Inventive) | (MW = 450000 g/mol) | | |
| 2E | polyacrylic acid | 1253 | 1633 |
| (Inventive) | (ALCOSPERSE ™ 630 | | |
| | MW = 65000 g/mol) | | |
| 2F | none | 1512 | 1684 |
| (Comparative) | | | |

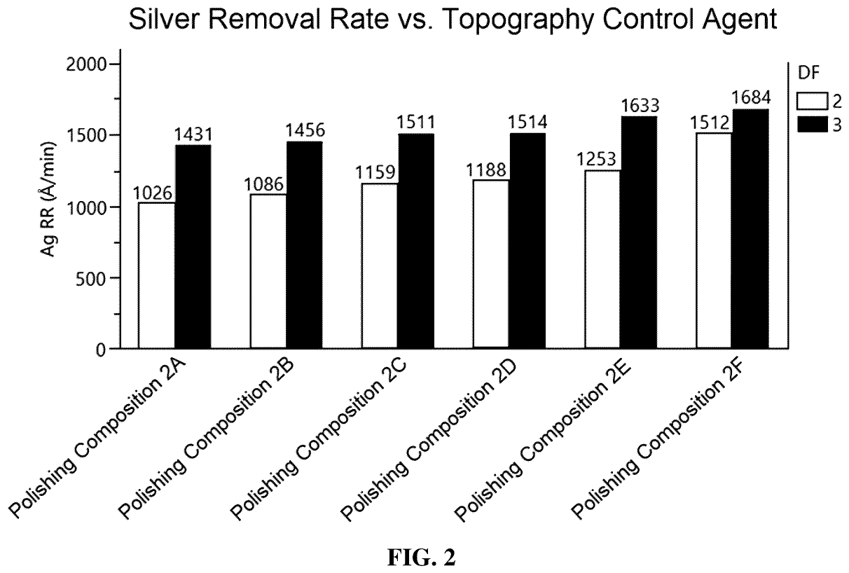

Silver wafers (200 mm) were polished with Polishing Compositions 2A-2F, as set forth in Table 2, using an Applied Materials Mirra polishing machine at 2 psi (13.7 kPA) or 3 psi (20.55 kPa) downforce using a NexPlanar™ U5050 pad (CMC Materials Inc.) conditioned with a product commercially identified as Diamond Pad Conditioner A82 (3M, St. Paul, MN). Mirra polishing parameters were as follows: head speed=87 rpm, platen speed=93 rpm, total flow rate=100 mL/min. All blanket substrates were polished for 20 seconds. Silver removal rates were calculated by measuring the film thickness, using KLA Tencor RS75 resistivity measurement, and subtracting the final thickness from the initial thickness. The results are set forth in Table 2 and FIG. 2.

As is apparent from the results set forth in Table 2 and FIG. 2, inventive Polishing Compositions 2A-2E, containing a topography control agent, could be easily tuned by adjusting the downforce of the polishing pad, as evidenced by a noticeable difference between the silver removal rate at a downforce of 2 psi and the silver removal rate at a downforce of 3 psi as compared to comparative Polishing Composition 2F, which does not exhibit a noticeable difference between the silver removal rate at a downforce of 2 psi and the silver removal rate at a downforce of 3 psi.

### Example 3

This example provides the silver removal rates for comparative formulations which do not include a polishing promoter compound or a topography control agent as required by the present invention.

Polishing Compositions 3A-3I contained, after 6× dilution at the point-of-use, 1000 ppm of DEQUEST™ 2010 (etidronic acid), 150 ppm α-Sulfo-ω-[1-[(nonylphenoxy)methyl]-2-(2-propenyl-oxy)ethoxy]-poly(oxy-1,2-ethandiyl), ammonium salt (CAS No. 184719-88-8), 300 ppm 1H-1,2,3-triazolo[4,5-b]pyridine (TAP), 16.7 ppm of PROXEL™ AQ, 1.0 wt. % hydrogen peroxide, and 0.3 wt. % of negatively-charged silica abrasive, having the average particle diameter set forth in Table 3. The resulting composition was adjusted to a pH of 9.6 with ammonium hydroxide.

TABLE 3
Abrasive Particle Diameter of Comparative
Polishing Compositions 3A-3I

| Polishing | Silica Abrasive Average |
|---|---|
| Composition | Particle Diameter (nm) |
| 3A | 28 |
| (Comparative) | |
| 3B | 45 |
| (Comparative) | |
| 3C | 18 |
| (Comparative) | |
| 3D | 35 |
| (Comparative) | |
| 3E | 70 |
| (Comparative) | |
| 3F | 20 |
| (Comparative) | |
| 3G | 40 |
| (Comparative) | |
| 3H | 35 |
| (Comparative) | |
| 3I | 120 |
| (Comparative) | |

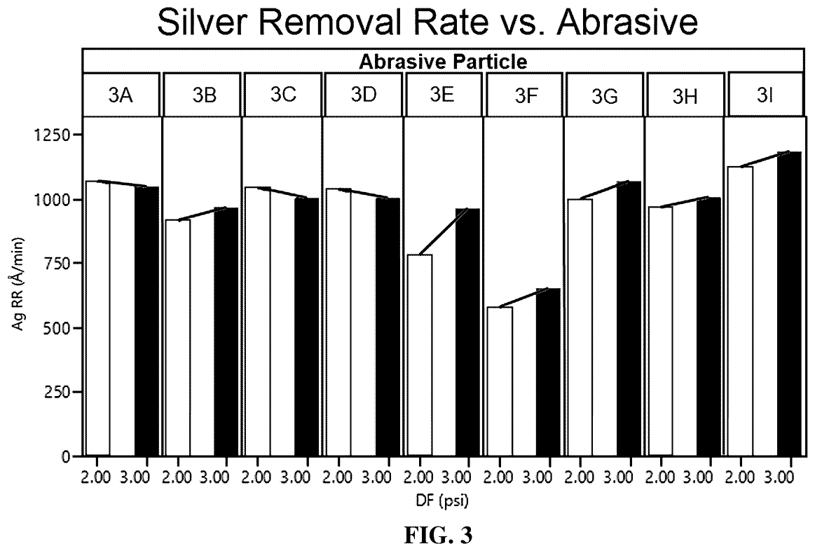

Silver wafers (200 mm) were polished with Polishing Compositions 3A-3I, as set forth in Table 3, using an Applied Materials Mirra polishing machine at 2 psi (13.7 kPA) or 3 psi (20.55 kPa) downforce using a NexPlanar™ U5050 pad (CMC Materials Inc.) conditioned with a product commercially identified as Diamond Pad Conditioner A82 (3M, St. Paul, MN). Mirra polishing parameters were as follows: head speed=87 rpm, platen speed=93 rpm, total flow rate=100 mL/min. All blanket substrates were polished for 20 seconds. Silver removal rates were calculated by measuring the film thickness, using KLA Tencor RS75 resistivity measurement, and subtracting the final thickness from the initial thickness. The results are set forth in FIG. 3.

As is apparent from the results set forth in FIG. 3, comparative Polishing Compositions 3A-3I, which do not contain a polishing promoter compound and topography control agent as required by the present invention, exhibited only moderate silver removal rates, regardless of the particle size of the silica abrasive included in the polishing composition. In addition, FIG. 3 shows that comparative Polishing Compositions 3A-3I, which do not contain a polishing promoter compound and topography control agent as required by the present invention, exhibited minimal or no tunability at downforces of 2 psi and 3 psi despite testing a variety of different silica abrasives.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) an abrasive selected from a silica abrasive, an alumina abrasive, and a combination thereof, wherein the polishing composition comprises about 0.001 wt. % to about 10 wt. % of the abrasive,
(b) about 0.1 wt. % to about 10 wt. % of a polishing promoter compound comprising (i) at least two nitrogen atoms and (ii) at least two chemical moieties selected from a phosphonic acid, a carboxylic acid, an alcohol, an anhydride, and a combination thereof,
(c) about 100 ppm to about 5000 ppm of a topography control agent comprising a nonionic polymer, an anionic polymer, or a combination thereof,
(d) about 100 ppm to about 5000 ppm of a corrosion inhibitor, and
(e) water, wherein the polishing composition has a pH of about 2 to about 10.

2. The polishing composition of claim 1, wherein the polishing composition comprises about 0.1 wt. % to about 5 wt. % of the abrasive.

3. The polishing composition of claim 1, wherein the polishing composition has a pH of about 7 to about 9.

4. The polishing composition of claim 1, wherein the polishing promoter compound comprises at least one group selected from —N(CH₂P(O)(OH)₂)₂ group, —N(CH₂CO₂H)₂ group, —N(CH₂CH₂OH)₂ group, 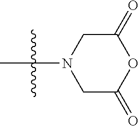 [SMILES: *N1CC(=O)OC(=O)C1]
group, salts thereof, and combinations thereof.

5. The polishing composition of claim 1, wherein the polishing promoter compound comprises at least two groups selected from —N(CH₂P(O)(OH)₂)₂ groups, —N(CH₂CO₂H)₂ groups, —N(CH₂CH₂OH)₂ groups, 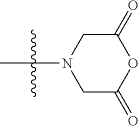 [SMILES: *N1CC(=O)OC(=O)C1]
groups, salts thereof, and combinations thereof.

6. The polishing composition of claim 1, wherein the polishing promoter compound is selected from ethylenediaminetetraacetic acid (EDTA), 1,2-cyclohexanediaminetetracetic acid (CyDTA), diethylenetriamine pentaacetic acid (DTPA), ethylenediamine-N,N,N′,N′-tetra-2-propanol (EDTP), ethyleneglycol-bis(β-aminoethyl)-N,N,N′,N′-tetraacetic acid (EGTA), hydroxyethylethylenediaminetriacetic acid (HEDTA), ethylenediamine tetra(methylene phosphonic acid) (EDTMP), N,N′-bis(salicylidene)ethylenediamine, diethylenetriaminepentaacetic dianhydride, ethylenediaminetetraacetic dianhydride, diethylenetriamine penta(methylene phosphonic acid) (DTPMP), salts thereof, and combinations thereof.

7. The polishing composition of claim 1, wherein the topography control agent comprises polyvinylalcohol (PVA), glycerin, polyethyeneglycol (PEG), polypropyleneglycol (PPG), a copolymer of ethylene glycol and propylene glycol, polyvinylpyrrolidon (PVP), poly(meth)acrylic acid, poly(meth)acrylamide, polyallylamine, a copolymer of (meth)acrylic acid and hydroxypropyl (meth)acrylate, a copolymer of (meth)acrylic acid and maleic acid, a salt thereof, or a combination thereof.

8. The polishing composition of claim 1, wherein the polishing composition comprises about 500 ppm to about 3000 ppm of the topography control agent.

9. The polishing composition of claim 1, wherein the corrosion inhibitor is selected from 1H-1,2,3-triazolo[4,5-b]pyridine (TAP), 1,2,3-benzotriazole (BTA), adenosine, adenine, dicyandiamide, 1,2,4-triazole (TAZ), 1H-1,2,3-triazole, 3-amino-1,2,4-triazole (ATA), pyrimidine, 1,2,4-trizaole-3-thiol, tolyltriazole, salts thereof, and combinations thereof.

10. The polishing composition of claim 1, wherein the polishing composition comprises about 500 ppm to about 3000 ppm of the corrosion inhibitor.

11. A method of chemically-mechanically polishing a substrate comprising:
(i) providing a substrate,
(ii) providing a polishing pad,
(iii) providing a chemical-mechanical polishing composition comprising:
(a) about 0.001 wt. % to about 10 wt. % an abrasive selected from a silica abrasive, an alumina abrasive, and a combination thereof,
(b) about 0.1 wt. % to about 10 wt. % of a polishing promoter compound comprising (i) at least two nitrogen atoms and (ii) at least two chemical moieties selected from a phosphonic acid, a carboxylic acid, an alcohol, an anhydride, and a combination thereof,
(c) 100 ppm to about 5000 ppm of a topography control agent comprising a nonionic polymer, an anionic polymer, or a combination thereof,
(d) about 100 ppm to about 5000 ppm of a corrosion inhibitor, and
(e) water,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

12. The method of claim 11, wherein the polishing composition comprises about 0.1 wt. % to about 5 wt. % of the abrasive.

13. The method of claim 11, wherein the polishing composition has a pH of about 7 to about 9.

14. The method of claim 11, wherein the polishing promoter compound comprises at least one group selected from —N(CH₂P(O)(OH)₂)₂ group, —N(CH₂CO₂H)₂ group, —N(CH₂CH₂OH)₂ group, 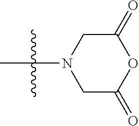 [SMILES: *N1CC(=O)OC(=O)C1]
group, salts thereof, and combinations thereof.

15. The method of claim 11, wherein the polishing promoter compound is selected from ethylenediaminetetraacetic acid (EDTA), 1,2-cyclohexanediaminetetracetic acid (CyDTA), diethylenetriamine pentaacetic acid (DTPA), ethylenediamine-N,N,N′,N′-tetra-2-propanol (EDTP), ethyleneglycol-bis(β-aminoethyl)-N,N,N′,N′-tetraacetic acid (EGTA), hydroxyethylethylenediaminetriacetic acid (HEDTA), ethylenediamine tetra(methylene phosphonic acid) (EDTMP), N,N′-bis(salicylidene)ethylenediamine, diethylenetriaminepentaacetic dianhydride, ethylenediaminetetraacetic dianhydride, diethylenetriamine penta(methylene phosphonic acid) (DTPMP), salts thereof, and combinations thereof.

16. The method of claim 11, wherein the topography control agent comprises polyvinylalcohol (PVA), glycerin, polyethyeneglycol (PEG), polypropyleneglycol (PPG), a copolymer of ethylene glycol and propylene glycol, polyvinylpyrrolidon (PVP), poly(meth)acrylic acid, poly(meth)acrylamide, polyallylamine, a copolymer of (meth)acrylic acid and hydroxypropyl (meth)acrylate, a copolymer of (meth)acrylic acid and maleic acid, a salt thereof, or a combination thereof.

17. The method of claim 11, wherein the corrosion inhibitor is selected from 1H-1,2,3-triazolo[4,5-b]pyridine (TAP), 1,2,3-benzotriazole (BTA), adenosine, adenine, dicyandiamide, 1,2,4-triazole (TAZ), 1H-1,2,3-triazole, 3-amino-1,2,4-triazole (ATA), pyrimidine, 1,2,4-trizaole-3-thiol, tolyltriazole, salts thereof, and combinations thereof.

18. The method of claim 11, wherein the corrosion inhibitor comprises 1H-1,2,3-triazolo[4,5-b]pyridine (TAP) or a salt thereof.

19. The method of claim 11, wherein the substrate comprises silver on a surface of the substrate, and wherein at least a portion of the silver on the surface of the substrate is abraded at a removal rate (Å/min) to polish the substrate.

20. The method of claim 19, wherein the substrate is contacted with the polishing pad at a downforce of about 5 kPa to about 50 kPa.
